(19) United States
(12) Patent Application Publication
(10) Pub. No.: US 2008/0310112 A1
(43) Pub. Date: Dec. 18, 2008

(54) System and Method for Providing Dewpoint Control in an Electrical Enclosure

(75) Inventors: Joseph Milton Long, Greencastle, PA (US); Delmar Eugene Lehman, Chambersburg, PA (US)

Correspondence Address: MCNEES WALLACE & NURICK LLC, 100 PINE ST., P.O. BOX 1166, HARRISBURG, PA, 17108-1166, US

(73) Assignee: JOHNSON CONTROLS TECHNOLOGY COMPANY, Holland, MI (US)

(21) Appl. No.: 11/762,518

(22) Filed: Jun. 13, 2007

(51) Int. Cl. H05K 7/20

(52) U.S. Cl. 361/701; 165/139; 62/132

(57) ABSTRACT

A system and method is provided for an electrical component enclosure that controls the temperature of the coolant in the internal coolant loop through the enclosure to prevent the formation of condensation on the coolant tubes. Warm coolant is diverted from a heat exchanger to a mixing valve where it is mixed with chilled coolant before entering the enclosure. Humidity and temperature levels are monitored within the enclosure and processed by a microprocessor to determine the temperature of the coolant needed in the tubes.

### BACKGROUND

The application generally relates to cooling electrical systems. More specifically, the present application is directed to a system and method for cooling electrical systems in an enclosure that prevents the formation of condensation within the enclosure by adjusting the temperature of a circulating coolant in response to the levels of humidity and temperature in the enclosure.

As electronic circuitry becomes available with more densely packed circuit components, the thermal energy flux produced by these devices increases significantly. Additionally, as these devices are operated at increased clock cycle frequencies, the power required by and within these devices also increases. Accordingly, cooling of electronic circuit components has become an increasingly more significant problem as a result of changes that are continuing to occur in the underlying technology. In addition, electrical components with a larger capacity, i.e., operating with larger voltages, such as power transistors, generate a significant amount of heat during operation. Therefore an electrical enclosure housing these larger capacity components requires even more cooling than an enclosure with smaller capacity electrical components.

A very significant thermophysical behavior is that by operating electronic circuit components, such as computer processors, at lower junction temperatures, these devices run at higher speeds. However, as the junction temperature of these devices decreases through the use of cooling mechanisms, there is a concomitant problem produced because the temperature of the outer surface of the package housing also decreases. Eventually, as the temperature is lowered, the temperature of the outer skin of the package, including electrical interconnections, drops below the dew point temperature of the ambient atmosphere and water starts to condense. This water vapor has the propensity to cause electrical short circuits. In addition, the larger capacity electrical components are extremely expensive to replace in the event of damage or failure, thus it is even more important to protect these components from any condensed water droplets to prevent shorting out and damaging the components.

The dew point temperature of a space indicates the amount of moisture in the air. The higher the dew point, the higher the moisture content of the air at a given temperature. Dew point temperature is defined as the temperature to which the air would have to cool (at constant pressure and constant water vapor content) in order to reach saturation. A state of saturation exists when the air is holding the maximum amount of water vapor possible at the existing temperature and pressure.

Relative humidity can be inferred from dew point values. When air temperature and dew point temperatures are very close, the air has a high relative humidity. The opposite is true when there is a large difference between air and dew point temperatures, which indicates air with lower relative humidity. Locations with high relative humidities indicate that the air is nearly saturated with moisture.

When the dew point temperature and air temperature are equal, the air is said to be saturated. Dew point temperature is never greater than the air temperature. Therefore, if the air cools, moisture must be removed from the air and this is accomplished through condensation. This process results in the formation of tiny water droplets that can lead to the development of fog, frost, clouds, or even precipitation. In electrical enclosures, these droplets can form on coolant tubes used to cool the enclosure or on other surfaces and may eventually fall onto electrical components within the enclosure causing failure or even destruction of the components.

Intended advantages of the systems and/or methods satisfy one or more of these needs or provide other advantageous features. Other features and advantages will be made apparent from the present specification. The teachings disclosed extend to those embodiments that fall within the scope of the claims, regardless of whether they accomplish one or more of the aforementioned needs.

### SUMMARY

One embodiment is directed to a cooling system for an electrical enclosure including a coolant loop configured and disposed to circulate a heat exchange fluid through an enclosure, the coolant loop having a main flow path with a heat exchanger disposed outside the enclosure to cool the heat exchange fluid and a coil disposed inside the enclosure to exchange heat with components within the enclosure and having a secondary flow path parallel to the heat exchanger. The system also includes a mixing valve configured and disposed to combine heat exchange fluids from the main flow path and the secondary flow path and provide a mixed heat exchange fluid to the coil, a temperature sensor disposed in the enclosure to measure a temperature level in the enclosure and a humidity sensor disposed in the enclosure to measure a humidity level in the enclosure. The system further includes a control system configured to receive the temperature and humidity level information from the temperature and humidity sensors and determine a dew point of the enclosure. The control system is configured to determine a temperature of the mixed heat exchange fluid to be provided to the coil, the temperature of the mixed heat exchange fluid being greater than the dew point by a predetermined offset. The control system is configured to generate control signals to position the mixing valve to combine heat exchange fluids from the main flow path and the secondary flow path in order to generate the determined temperature of the mixed heat exchange fluid to be provided to the coil.

Another embodiment is directed to a variable speed drive assembly including a thermally insulative and substantially airtight enclosure and a converter, DC link and inverter disposed in the enclosure. The variable speed drive assembly also includes a cooling system configured and disposed to circulate a fluid through the enclosure. The cooling system having a main flow path with a heat exchanger disposed outside the enclosure to cool the fluid in the main flow path and a coil disposed inside the enclosure to cool at least one of the converter, the DC link or the inverter, a secondary flow path is disposed parallel to the heat exchanger and a mixing valve configured and disposed to combine fluids from the main flow path and the secondary flow path and provide a mixed fluid to the coil. The system also includes a temperature sensor disposed in the enclosure to measure a temperature level in the enclosure, a humidity sensor disposed in the enclosure to measure a humidity level in the enclosure and a control system configured to receive temperature and humidity level information from the temperature and humidity sensors to determine a dew point of the enclosure. The control system is configured to determine a temperature of the mixed fluid to be provided to the coil. The temperature of the mixed fluid being greater than the dew point by a predetermined offset. The control system is configured to generate control signals to position the mixing valve to combine fluid from the main flow path and the secondary flow path to generate the temperature of the mixed fluid to be provided to the coil.

Still another embodiment is directed to a method for providing dew point control in an electrical enclosure including providing a coolant loop configured and disposed to circulate a heat exchange fluid through a heat exchanger in an enclosure. The method also includes measuring the temperature level in the electrical enclosure with a temperature sensor, measuring the humidity level in the electrical enclosure with a humidity sensor, and calculating the dew point level of the enclosure based on the measured temperature and humidity levels. Further, the method includes determining a temperature of the heat exchange fluid to be circulated to the heat exchanger based on the calculated dew point level, with the determined temperature of the heat exchange fluid being greater than the calculated dew point level. The method also includes positioning a mixing valve to combine heat exchange fluids from a first portion of the coolant loop having cooled heat exchange fluid with heat exchange fluid from a second portion of the coolant loop having uncooled heat exchange fluid to generate the determined temperature of the heat exchange fluid and prevent the formation of condensation within the enclosure. The temperature of the heat exchange fluid is greater than the calculated dew point level and the temperature of the heat exchange fluid from the first portion of the coolant loop is greater than the temperature of the heat exchange fluid from the second portion of the coolant loop.

Certain advantages of the embodiments described herein are the use of a fluid from the refrigeration system that avoids the need for an entirely separate cooling circuit and the temperature of the enclosure is prevented from reaching the dew point temperature.

Alternative exemplary embodiments relate to other features and combinations of features as may be generally recited in the claims.

### BRIEF DESCRIPTION OF THE FIGURES

FIG. 1 is a schematic diagram of a refrigeration system.

FIG. 2 is a schematic diagram of the enclosure cooling system.

FIG. 3 is an embodiment of a control process.

FIG. 4 illustrates the placement of the coolant components in the enclosure in one embodiment.

### DETAILED DESCRIPTION OF THE EXEMPLARY EMBODIMENTS

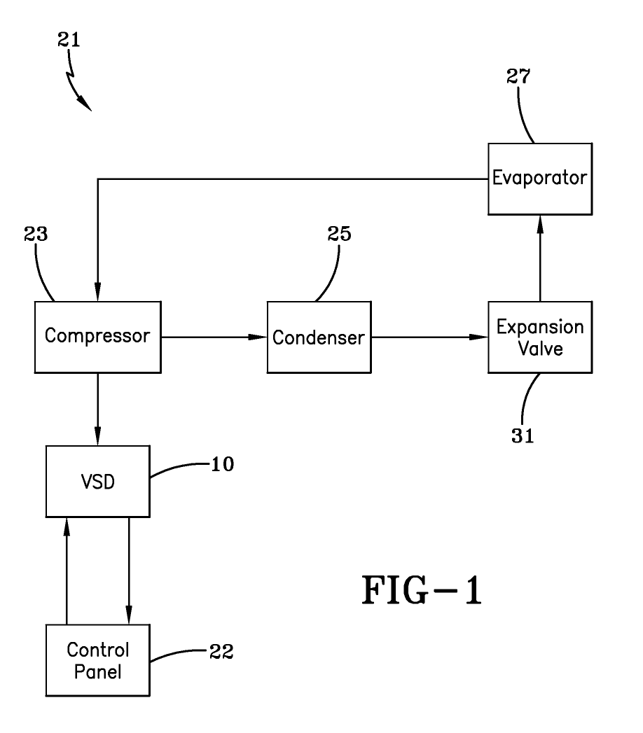

The application is directed to cooling electrical systems and preventing the formation of condensation within an electrical enclosure by adjusting the coolant temperature in response to the levels of humidity and temperature in the space. FIG. 1 is a schematic diagram of a refrigeration system 21. The refrigeration system 21 includes a compressor 23, a condenser arrangement 25, an evaporator arrangement 27 and a valve arrangement 31. Compressor 23 compresses a refrigerant vapor and delivers the vapor to condenser 25. Compressor 23 can be a scroll compressor, rotary compressor, screw compressor, swing link compressor, reciprocating compressor, centrifugal compressor or any other suitable compressor. The refrigerant vapor delivered by compressor 23 to condenser 25 enters into a heat exchange relationship with a fluid, e.g., air or water, and undergoes a phase change to a refrigerant liquid as a result of the heat exchange relationship with the fluid. The condensed refrigerant liquid from condenser 25 flows through an expansion device 31 to evaporator 27.

The condensed refrigerant liquid delivered to evaporator 27 enters into a heat exchange relationship with a fluid, e.g., air, water, or other secondary coolant such as brine or ethylene glycol, and undergoes a phase change to a refrigerant vapor as a result of the heat exchange relationship with the fluid. The refrigerant vapor in evaporator 27 exits evaporator 27 and returns to compressor 23 by a suction line to complete the cycle. It is to be understood that any suitable configuration of condenser 25 and evaporator 27 can be used in system 21, provided that the appropriate phase change of the refrigerant in condenser 25 and evaporator 27 is obtained. The refrigeration system 21 can include many other features that are not shown in FIG. 1.

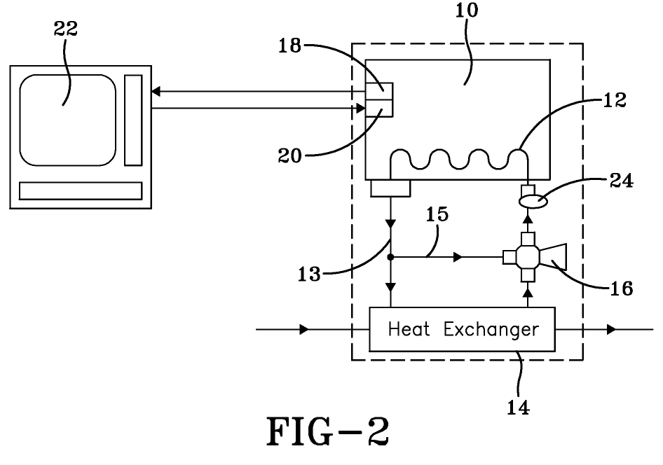

FIG. 2 illustrates one embodiment of the present invention in which the components to be cooled are contained within an enclosure 10 which is thermally insulative and is substantially airtight. Enclosure 10 may include, but is not limited to, NEMA 4 or IEC IP66 rated enclosures, however any suitable enclosure can be used. Enclosure 10 also includes an internal coolant loop 12 that provides cooling to the components inside enclosure 10. As part of the internal coolant loop 12, a coil (not shown) operates to provide additional cooling to the components. The coil can be a heat exchanger with fins in communication with the heat dissipated from the electrical components in enclosure 10. In addition, temperature and humidity sensors 18, 20 are located inside the enclosure to monitor the temperature and humidity levels within the enclosure. The components disposed in enclosure 10 can be larger capacity components that typically provide 150 to 1100 horsepower for equipment operation, e.g., motors, or require at least 460 volts of electricity to operate. The components have a capacity to produce high temperatures within enclosure 10, which can cause destruction of the components if the temperature is not controlled. Thus, internal coolant loop 12 is placed within enclosure 10 to cool the enclosure area and prevent the failure of the components.

FIG. 2 also illustrates the associated coolant system connected to internal coolant loop 12 for enclosure 10. Warm heat exchange fluid exits internal coolant loop 12 and flows toward a heat exchanger 14. A portion of the heated heat exchange fluid is diverted from a main flow path 13 before arriving at heat exchanger 14 and is passed through a secondary flow path 15 to a mixing valve 16. The remainder of the heat exchange fluid passes to heat exchanger 14 where the heat exchange fluid is chilled and then passed to the mixing valve 16. Heat exchanger 14 can be incorporated in condenser 25 or have connections to use the fluid circulating in condenser 12 or evaporator 27. For purposes of this present application, the term “heat exchange fluid”, “heat exchange liquid”, or “heat exchange vapor” includes, but is not limited to, refrigerants, cooling tower water, ground water, a brine solution, or any other suitable heat exchange fluid. In addition, the brine solution is not restricted to water and salt, but may instead be glycol brines made from mixtures of water with glycerine, ethylene glycol, or propylene glycol to provide noncorrosive solutions if necessary.

Temperature sensors 18 and humidity sensors 20 monitor the temperature and humidity levels in enclosure 10. These temperature and humidity measurements are sent to a microprocessor control 22 that uses the measured levels to calculate the dew point of enclosure 10. Microprocessor 22 determines the dew point, or wet bulb temperature, of enclosure 10 and sends a signal to mixing valve 16. This signal controls the amount of heat exchange fluid in secondary flow path 15 that is mixed by mixing valve 16 with the heat exchange fluid from heat exchanger 14 by controlling the position of mixing valve 16. The mixing valve 16 responds to the signal by moving to the determined position and allowing a specific amount of the heat exchange fluid from the second or secondary flow path 15 to mix with a specific amount of heat exchange fluid from heat exchanger 14 in main flow path 13. The heat exchange fluid from second flow path 15 has a higher temperature since it was diverted from the main flow path before passing through the heat exchanger. The heat exchange fluid in main flow path 13 leaving heat exchanger 14 has a lower temperature because it passed through heat exchanger 14 and was cooled. The mixture of chilled and warmer heat exchange fluid from the second and main flow paths 13, 15 prevents the heat exchange fluid from entering into enclosure 10 at a temperature below the dew point temperature of enclosure 10. Circulating pump 24 creates the force to flow the heat exchange fluid through internal coolant loop 12 and back to heat exchanger 14 and mixing valve 16 to repeat the process. The system may also include temperature sensors in the secondary flow path to monitor the actual temperature of the heat exchange fluid in that line. Further, temperature sensors may monitor the actual temperature of the heat exchange fluid in the main flow path entering and/or leaving the heat exchanger. This provides more information for the processor to determine how much of each heat exchange fluid to mix in mixing valve 16 before returning it into the electrical cabinet. Alternately, mixing valve 16 may be disposed in the system before heat exchanger 14. The heat exchange fluid would exit enclosure 10 and flow through main flow path 13 and directly to the mixing valve. Depending on the signals microprocessor 22 receives from the temperature sensors, mixing valve 16 is controlled to regulate how much of the heat exchange fluid flows through secondary flow path 15 to bypass heat exchanger 14 and the amount of heat exchange fluid that flows through heat exchanger 14.

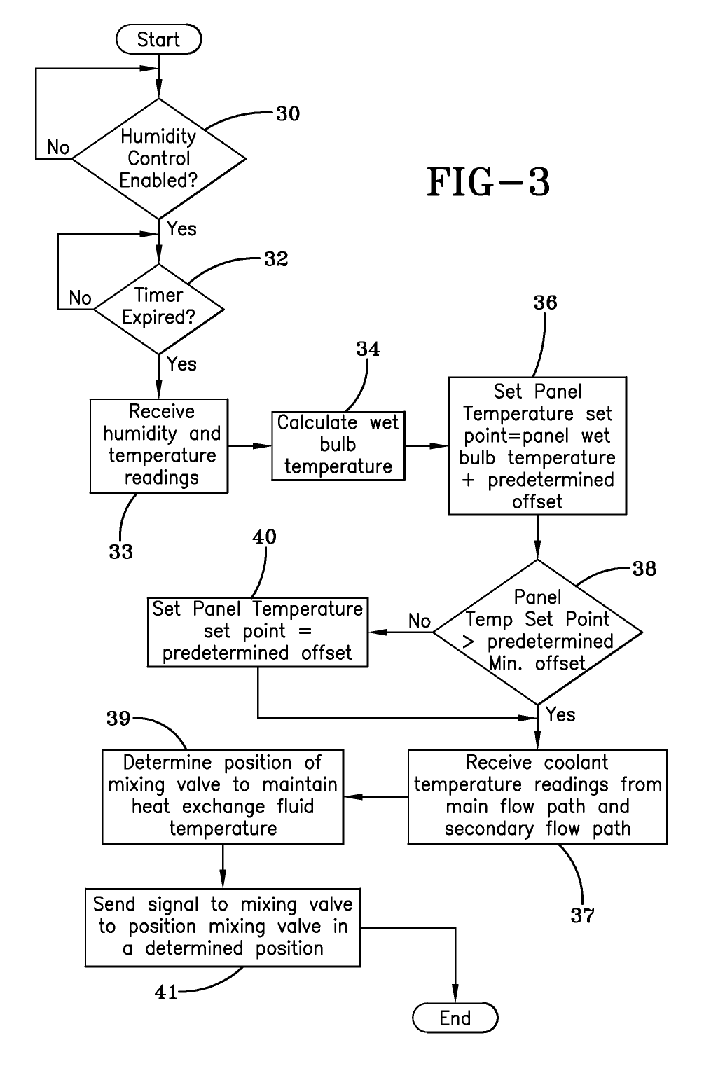

FIG. 3 illustrates of embodiment the control process. In step 30, microprocessor 22 checks if the humidity control is enabled. If the humidity control is not enabled, then microprocessor 22 repeats Step 30 until the humidity control is enabled. If and when the humidity control is enabled, microprocessor 22 checks if a predetermined timer, e.g., five minutes, have expired in Step 32. A timer is used to compensate for the gradual change in temperatures outside enclosure 10. A calculation for this change is done at regular intervals, e.g., every five minutes, to ensure system stabilization and to assist with central processing unit (CPU) processing. If the timer has not expired, then microprocessor 22 repeats Step 32 until the timer does expire. Once the predetermined timer has expired, microprocessor 22 continues to Step 33 where the humidity and temperature readings are received from the sensors in the enclosure. In Step 34, the wet bulb temperature, or dew point temperature, of enclosure 10 is calculated by using the humidity and temperature levels measured within enclosure 10. Microprocessor 22 then sets the temperature set point in the enclosure to the wet bulb temperature plus a predetermined offset amount, e.g., five degrees Fahrenheit, in Step 36. Next, in Step 38, microprocessor 22 checks if this new temperature set point is greater than a predetermined minimum temperature setpoint, e.g., fifty degrees Fahrenheit. In addition, dew point formation levels are higher at enclosure temperatures that are less than substantially fifty degrees Fahrenheit, thus it is intended to maintain an enclosure temperature level for operation at substantially fifty degrees Fahrenheit or higher to maintain lower dew point formation levels. If the temperature set point is not greater than the predetermined minimum temperature set point, then the temperature set point is reset to equal to the predetermined minimum set point in Step 40. If, in Step 38, the set point temperature is greater than the predetermined minimum temperature set point, microprocessor 22 receives the heat exchange fluid temperature readings from main flow path 13 and secondary flow path 15 in Step 37. Based on the calculated wet bulb temperature from Step 34 and the heat exchange fluid temperature in Step 37, microprocessor 22 determines a position of the mixing valve that allows a controlled temperature of heat exchange fluid to enter enclosure 10 in coolant loop 12 in Step 39. A signal is then sent to the mixing valve in Step 41 to control the mixing valve to move to the predetermined position.

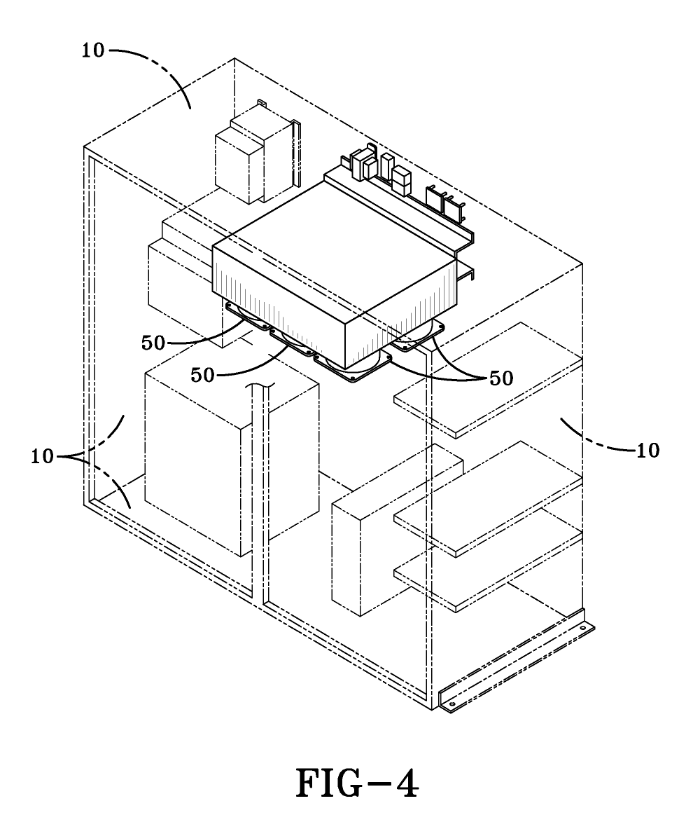

FIG. 4 illustrates one embodiment of an enclosure 10 and cooling loop 12 used for cooling enclosure 10. Loop 12 is disposed inside of enclosure 10 to provide cooling to the electrical components within enclosure 10. While loop 12 is shown in FIG. 4 to be disposed in a particular location of enclosure 10, loop 12 can be disposed anywhere suitable for operation within enclosure 10. A fan and coil assembly 50 is disposed within enclosure 10. The coil can include fins in communication with the heat dissipated from the electrical components in enclosure 10. The fan is used to circulate the air past the cooling fins and coil and throughout enclosure 10 to reduce the temperature in enclosure 10.

Another embodiment includes a cold plate assembly that is secured to the electrical components to absorb the dissipated heat. The cold plate is provided to cool the components that tend to operate at faster speeds and at higher temperatures and are in more critical need of cooling. The electronics can be in thermal contact with the cold plate assembly, which has channels through which the heat exchanger fluid can flow. These channels allow the cold plate assembly to provide cooling to some of the electronics in enclosure 10.

Another embodiment includes a desiccant disposed in the enclosure 10. The desiccant absorbs excess moisture in the air within the enclosure to reduce the humidity levels. With reduced humidity levels, the dew point temperature is reduced resulting in a drier atmospheric environment for the electrical components and the coolant tubes in enclosure 10. The drier air in the enclosure allows the heat exchange fluid in the coolant tubes to be at a lower temperature. In addition, since the heat exchange fluid is set at a lower temperature, the enclosure is cooled more effectively and to a lower temperature, which is beneficial for the electronic equipment. The cooler the environment in which the equipment is disposed, the longer useful life the equipment will provide, thus reducing replacement costs and time. Suitable materials for the desiccant can include, but are not limited to a silica gel, calcium chloride, activated alumina, lithium chloride or calcium sulfate.

It should be understood that the application is not limited to the details or methodology set forth in the following description or illustrated in the figures. It should also be understood that the phraseology and terminology employed herein is for the purpose of description only and should not be regarded as limiting.

While the systems and methods of the application have been described with reference to a several embodiments, it will be understood by those skilled in the art that various changes may be made and equivalents may be substituted for elements thereof without departing from the scope of the application. In addition, many modifications may be made to adapt a particular situation or material to the teachings of the application without departing from the essential scope thereof. Therefore, it is intended that the system and methods of the application not be limited to the particular embodiment disclosed as the best mode contemplated for carrying out the system and methods of the application, but that the system and methods of the application will include all embodiments falling within the scope of the appended claims.

It is important to note that the construction and arrangement of the system as shown in the various exemplary embodiments is illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited in the claims. For example, elements shown as integrally formed may be constructed of multiple parts or elements, the position of elements may be reversed or otherwise varied, and the nature or number of discrete elements or positions may be altered or varied. Accordingly, all such modifications are intended to be included within the scope of the present application. The order or sequence of any process or method steps may be varied or re-sequenced according to alternative embodiments. In the claims, any means-plus-function clause is intended to cover the structures described herein as performing the recited function and not only structural equivalents but also equivalent structures. Other substitutions, modifications, changes and omissions may be made in the design, operating conditions and arrangement of the exemplary embodiments without departing from the scope of the present application.

It should be noted that although the figures herein may show a specific order of method steps, it is understood that the order of these steps may differ from what is depicted. Also two or more steps may be performed concurrently or with partial concurrence. Such variation will depend on the software and hardware systems chosen and on designer choice. It is understood that all such variations are within the scope of the application. Likewise, software implementations could be accomplished with standard programming techniques with rule-based logic and other logic to accomplish the various connection steps, processing steps, comparison steps and decision steps.

What is claimed is:

1. A cooling system for an electrical enclosure, comprising:
a coolant loop configured and disposed to circulate a heat exchange fluid through an enclosure, the coolant loop having a main flow path and a secondary flow path, the main flow path having a heat exchanger disposed outside the enclosure to cool the heat exchange fluid and a coil disposed inside the enclosure to exchange heat with components within the enclosure, the secondary flow path is disposed parallel to the heat exchanger;
a mixing valve being configured and disposed to combine heat exchange fluids from the main flow path and the secondary flow path and provide a mixed heat exchange fluid to the coil;
a temperature sensor disposed in the enclosure to measure a temperature level in the enclosure;
a humidity sensor disposed in the enclosure to measure a humidity level in the enclosure;
a control system being configured to receive temperature and humidity level information from the temperature and humidity sensors and determine a dew point of the enclosure, the control system further being configured to determine a temperature of the mixed heat exchange fluid to be provided to the coil, the temperature of the mixed heat exchange fluid being greater than the dew point by a predetermined offset; and
wherein the control system is configured to generate control signals to position the mixing valve to combine heat exchanger fluids from the main flow path and the secondary flow path in order to generate the determined temperature of the mixed heat exchange fluid to be provided to the coil.

2. The cooling system of claim 1 wherein the control system comprises a microprocessor.

3. The cooling system of claim 1 further comprising a coolant temperature feedback sensor disposed in the main flow path to measure a temperature of heat exchange fluid leaving the enclosure and provide the fluid temperature to the control system, the control system being configured to use the fluid temperature in generating the control signal for the mixing valve.

4. The cooling system of claim 1 wherein the predetermined offset is about five degrees Fahrenheit.

5. The cooling system of claim 1 wherein the secondary flow path is disposed outside the enclosure and receives heat exchange fluid from the coil.

6. The cooling system of claim 1 wherein the temperature of the mixed heat exchange fluid to be provided to the coil is greater than a predetermined minimum set point.

7. The cooling system of claim 6 wherein the predetermined minimum set point is fifty degrees Fahrenheit.

8. The cooling system of claim 1 wherein the coil comprises a cold plate assembly secured to components of the enclosure to absorb heat dissipated from the components of the enclosure.

9. The cooling system of claim 1 further comprising a desiccant disposed inside the enclosure to reduce humidity levels.

10. The cooling system of claim 1 wherein the heat exchanger is connected to a refrigeration system to receive a cooling fluid to cool the heat exchange fluid from the enclosure.

11. The cooling system of claim 10 wherein the cooling fluid is refrigerant.

12. A variable speed drive assembly comprising:
a thermally insulative and substantially airtight enclosure;
a converter, a DC link and an inverter disposed in the enclosure;
a cooling system configured and disposed to circulate a fluid through the enclosure, the cooling system having a main flow path, a secondary flow path, and a mixing valve, the main flow path having a heat exchanger disposed outside the enclosure to cool the fluid in the main flow path and a coil disposed inside the enclosure to cool at least one of the converter, the DC link or the inverter, the secondary flow path being disposed parallel to the heat exchanger, the mixing valve being configured and disposed to combine fluids from the main flow path and the secondary flow path and provide a mixed fluid to the coil;
a temperature sensor disposed in the enclosure to measure a temperature level in the enclosure;
a humidity sensor disposed in the enclosure to measure a humidity level in the enclosure;
a control system being configured to receive temperature and humidity level information from the temperature and humidity sensors and determine a dew point of the enclosure, the control system further being configured to determine a temperature of the mixed fluid to be provided to the coil, the temperature of the mixed fluid being greater than the dew point by a predetermined offset; and
wherein the control system is configured to generate control signals to position the mixing valve to combine fluid from the main flow path and the secondary flow path in order to generate the determined temperature of the mixed fluid to be provided to the coil.

13. The variable speed drive assembly of claim 12 wherein the control system comprises a microprocessor.

14. The variable speed drive assembly of claim 12 further comprising a coolant temperature feedback sensor disposed in the main flow path to measure a temperature of fluid leaving the enclosure and provide the fluid temperature to the control system, the control system using the fluid temperature leaving the enclosure in generating the control signal for the mixing valve.

15. The variable speed drive assembly of claim 12 wherein the predetermined offset is about five degrees Fahrenheit.

16. The variable speed drive assembly of claim 15 wherein the secondary flow path is disposed outside the enclosure and receives fluid from the coil.

17. The variable speed drive assembly of claim 12 wherein the temperature of the mixed fluid provided to the coil is at least fifty degrees Fahrenheit.

18. The variable speed drive assembly of claim 12 wherein the coil comprises a cold plate assembly disposed in the enclosure to absorb dissipated heat from at lease one of the converter the DC link, or the inverter.

19. The variable speed drive assembly of claim 12 further comprising a desiccant disposed inside the enclosure to reduce humidity levels.

20. The variable speed drive assembly of claim 12 wherein the heat exchanger is connected to a refrigeration system to receive a cooling fluid to cool fluid from the enclosure.

21. The variable speed drive assembly of claim 20 wherein the cooling fluid is refrigerant.

22. A method for providing dew point control in an electrical enclosure comprising:
providing a coolant loop configured and disposed to circulate a heat exchange fluid through a heat exchanger in an enclosure;
measuring the temperature level in the electrical enclosure with a temperature sensor;
measuring the humidity level in the electrical enclosure with a humidity sensor;
calculating the dew point level of the enclosure based on the measured temperature and humidity levels;
determining a temperature of the heat exchange fluid to be circulated in the heat exchanger based on the calculated dew point level wherein the determined temperature of the heat exchange fluid is greater than the calculated dew point level; and
positioning a mixing valve to combine heat exchange fluid from a first portion of the coolant loop having cooled heat exchange fluid with heat exchange fluid from a second portion of the coolant loop having uncooled heat exchange fluid to generate the determined temperature of the heat exchange fluid to be circulated in the heat exchanger and prevent the formation of condensation within the enclosure, wherein the temperature of the heat exchange fluid from the first portion of the coolant loop is greater than the temperature of the heat exchange fluid from the second portion of the coolant loop.

23. The method of claim 22 wherein the determined temperature of the heat exchange fluid to be circulated in the heat exchanger is greater than the calculated dew point level by a predetermined offset.

24. The method of claim 22 further comprising measuring a temperature of heat exchange fluid leaving the enclosure with a coolant temperature feedback sensor disposed in the coolant loop, and using the measured temperature of heat exchange fluid leaving the enclosure to assist in positioning the mixing valve.

25. The method of claim 22 wherein the determined temperature of the heat exchange fluid is at least fifty degrees Fahrenheit.

26. The method of claim 22 wherein the heat exchanger is a cold plate assembly disposed in the enclosure to absorb dissipated heat from components.

27. The method of claim 22 further comprising the step of positioning a desiccant inside the enclosure to reduce humidity levels.
